(19) United States
(12) Patent Application Publication
(10) Pub. No.: US 2025/0157817 A1
(43) Pub. Date: May 15, 2025

(54) FILM FORMING METHOD, ARTICLE MANUFACTURING METHOD AND FILM FORMING APPARATUS

(71) Applicant: CANON KABUSHIKI KAISHA, Tokyo (JP)

(72) Inventors: MASAHIRO TAMURA, Tochigi (JP); TOSHIKI ITO, Kanagawa (JP); HIDEKI IMAMURA, Tochigi (JP)

(21) Appl. No.: 18/931,496

(22) Filed: Oct. 30, 2024

(30) Foreign Application Priority Data
Nov. 9, 2023 (JP) 2023-191718

(51) Int. Cl. H01L 21/027; G03F 7/00; G03F 7/16

(52) U.S. Cl. CPC H01L 21/0271; G03F 7/0002; G03F 7/168; G03F 7/70033

(57) ABSTRACT

A film forming method for forming a film of a curable composition in a space between a mold and a substrate, including discretely arranging a plurality of droplets of the curable composition on the substrate, after the discretely arranging, waiting until the plurality of droplets combine with adjacent droplets to form a liquid film, and a solvent contained in the liquid film volatilizes, after the waiting, bringing the liquid film and the mold into contact with each other, after the bringing, curing the liquid film to form a cured film, and after the curing, releasing the mold from the cured film, wherein in the waiting, an airflow including a flow of a gas parallel to a surface of the substrate is formed and the liquid film is exposed to the airflow.

### BACKGROUND OF THE INVENTION

### Field of the Invention

The present invention relates to a film forming method, an article manufacturing method and a film forming apparatus.

### Description of the Related Art

For semiconductor devices and MEMS, requirements of micronization are increasing, and as a micropatterning technique, an imprint technique (optical imprint technique) has received a great deal of attention as a microfabrication technique. In the imprint technique, a curable composition is cured in a state in which a mold with a fine uneven pattern formed on the surface is in contact with the curable composition supplied (applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order.

A photolithography step of fabricating a semiconductor device requires planarization of a substrate. For example, in an extreme ultraviolet exposure technique (EUV) as a photolithography technique attracting attention in recent years, the depth of focus at which a projected image is formed decreases as miniaturization advances, so the unevenness on the surface of a substrate to which a curable composition is supplied must be decreased to a few tens nm or less. Flatness equivalent to that of EUV is required in an imprint technique as well, in order to improve the filling properties of a curable composition and the line width accuracy. As a planarization technique, there is known a technique of obtaining a flat surface by discretely dropping, on an uneven substrate, droplets of a curable composition in an amount corresponding to the unevenness, and curing the curable composition in a state in which a mold having a flat surface is in contact with the curable composition.

In these techniques, as disclosed in Japanese Patent Laid-Open No. 2022-188736, there is known a technique of, to shorten time to fill a curable composition between a mold and a substrate, using a curable composition whose droplets combine with each other to form a liquid film before the mold and the curable composition on the substrate are brought into contact with each other. In a process using such a curable composition, a step of volatilizing a solvent contained in the curable composition needs to be performed before the mold is brought into contact with the curable composition.

In the conventional process, however, large film thickness unevenness may occur in the liquid film of the curable composition formed on the substrate depending on the environment in which the solvent contained in the curable composition volatilizes.

### SUMMARY OF THE INVENTION

The present invention provides a technique advantageous in forming a film of a curable composition having an excellent film thickness distribution in a space between a mold and a substrate.

According to one aspect of the present invention, there is provided a film forming method for forming a film of a curable composition in a space between a mold and a substrate, including discretely arranging a plurality of droplets of the curable composition on the substrate, after the discretely arranging, waiting until the plurality of droplets combine with adjacent droplets to form a liquid film, and a solvent contained in the liquid film volatilizes, after the waiting, bringing the liquid film and the mold into contact with each other, after the bringing, curing the liquid film to form a cured film, and after the curing, releasing the mold from the cured film, wherein in the waiting, an airflow including a flow of a gas parallel to a surface of the substrate is formed and the liquid film is exposed to the airflow.

Further aspects of the present invention will become apparent from the following description of exemplary embodiments with reference to the attached drawings.

### BRIEF DESCRIPTION OF THE DRAWINGS

FIGS. 1A to 1G are views for describing a pattern forming method according to the present invention.

FIGS. 2A and 2B are views illustrating an example of a waiting step according to the embodiment.

FIGS. 3A and 3B are views illustrating an example of a waiting step according to a comparative example.

FIGS. 4A and 4B are views illustrating an example of a waiting step according to a comparative example.

FIG. 5 is a view illustrating film thickness measurement points for a sample.

FIG. 6 is a schematic view illustrating configurations of a film forming apparatus according to an aspect of the present invention.

FIGS. 7A to 7F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

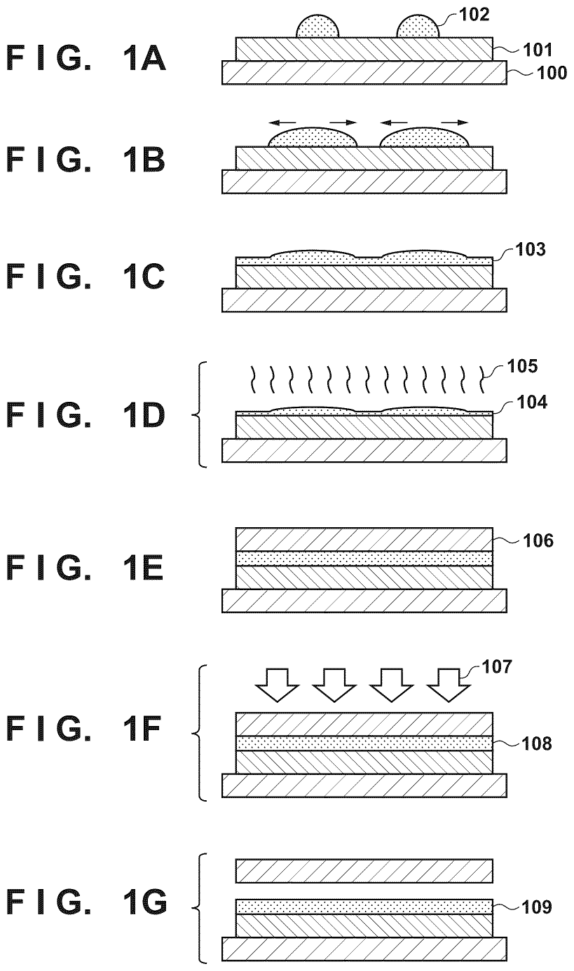

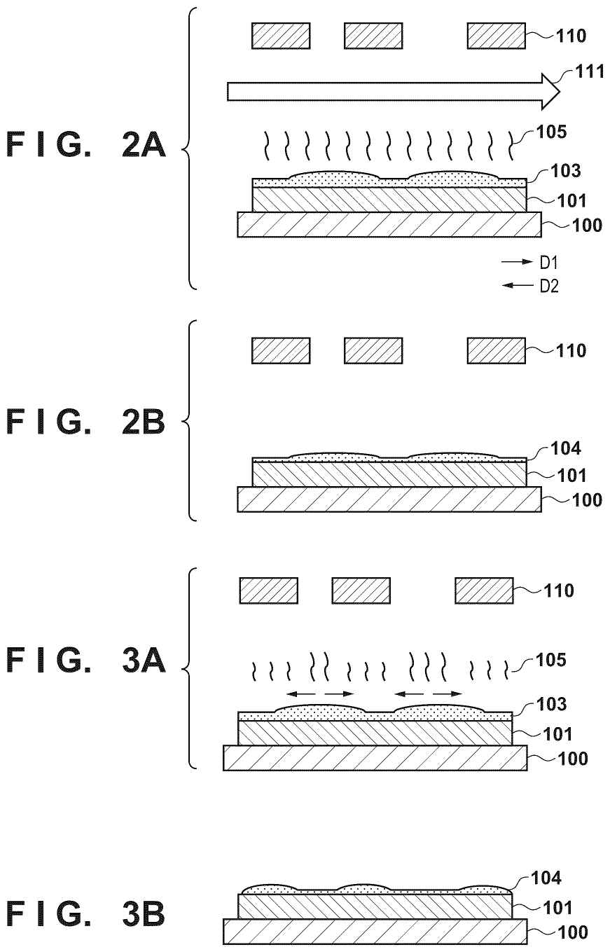

The pattern forming method of the present invention will be explained below with reference to FIGS. 1A to 1G. The cured film formed by the present invention is preferably a film having a pattern with a size of 1 nm or more and 10 mm or less, and more preferably a film having a pattern with a size of 10 nm or more and 100 μm or less. Generally, a film forming method of forming a film having a pattern (uneven structure) of a nano size (1 nm or more and 100 nm or less) by using light is called a photoimprint method. The film forming method of the present invention forms a film of a curable composition in a space between a mold and a substrate by using the photoimprint method. However, the curable composition can also be cured by another energy (for example, heat or an electromagnetic wave). A film forming method of the present invention can be performed as a method of forming a film having a pattern, that is, as a pattern forming method, and can also be performed as a method of forming a film (for example, a planarization film) having no pattern, that is, as a planarization film forming method.

An example in which a film forming method according to the present invention is applied to a pattern forming method will be described below. The pattern forming method includes, for example, an arranging step, a waiting step, a contact step, a curing step, and a mold release step. The arranging step is a step of discretely arranging a plurality of droplets of a curable composition on an underlayer formed on a substrate. The waiting step is a step of waiting until the droplets of the curable composition combine with each other (that is, the plurality of droplets of the curable composition combine with adjacent droplets), and a solvent contained in the curable composition volatilizes. The contact step is a step of bringing the curable composition on the substrate and a mold into contact with each other. The curing step is a step of curing the curable composition on the substrate. The mold release step is a step of releasing the mold from the cured film of the curable composition on the substrate. The waiting step is executed after the arranging step, the contact step is executed after the waiting step, the curing step is executed after the contact step, and the mold release step is executed after the curing step.

### <Arranging Step>

In the arranging step as schematically shown in FIG. 1A, droplets 102 of a curable composition are discretely arranged on a substrate 101 held by a stage 100. A substrate on which an underlayer is stacked can also be used as the substrate 101. In addition, the adhesion of the surface of the substrate 101 with respect to the curable composition can be improved by a surface treatment such as a silane coupling treatment, a silazane treatment, or deposition of an organic thin film.

An inkjet method is particularly favorable as the arranging method of arranging the droplets 102 of the curable composition on the substrate. It is favorable to arrange the droplets 102 of the curable composition densely on that region of the substrate 101, which faces a region in which recesses forming the pattern of a mold 106 densely exist, and sparsely on that region of the substrate 101, which faces a region in which recesses forming the pattern of the mold 106 sparsely exist. Consequently, a cured film 108 (residual film) (to be described later) of the curable composition formed on the substrate 101 is controlled to have a uniform thickness regardless of the sparsity and density of the pattern of the mold 106.

### <Waiting Step>

In this embodiment, the waiting step is provided after the arranging step and before the contact step. In the waiting step, the droplets 102 of the curable composition start spreading planarly, as schematically shown in FIG. 1B. Then, the adjacent droplets of the curable composition combine with each other to form a substantially continuous liquid film 103, as schematically shown in FIG. 1C. Further, as schematically shown in FIG. 1D, when the process waits until a solvent 105 contained in the liquid film 103 volatilizes, the liquid film 103 changes to a liquid film 104 that hardly flows planarly. As described above, the waiting step includes a first step until the liquid film 103 covers the whole region of the substrate 101 (a shot region on which a film should be formed), and a second step of waiting, after the first step, until the solvent 105 contained in the liquid film 103 covering the whole region of the substrate 101 volatilizes. Assuming that the total weight of the components except for the solvent is 100 vol %, the residual amount of the solvent in the liquid film 104 after the waiting step is preferably 10 vol % or less. If the residual amount of the solvent in the liquid film 104 is larger than 10 vol %, the mechanical properties of the cured film may deteriorate.

Also, in this embodiment, in the waiting step, as shown in FIG. 2A, when volatilizing the solvent 105 contained in the liquid film 103, an airflow 111 including a flow of a gas parallel to the surface (upper surface) of the substrate 101 is formed, and the liquid film 103 is exposed to the airflow 111. When the liquid film 103 is exposed to the airflow 111, the volatilization speed of the solvent 105 that volatilizes from the liquid film 103 is even in plane. This is because the airflow 111 can suppress occurrence of retainment of the solvent 105 that has volatilized from the liquid film 103 (in-plane unevenness of a vapor amount) in the upper space, which leads to unevenness of the volatilization speed. Here, to make the vapor amount constant in the space above the liquid film 103, the airflow 111 is preferably an airflow without any local excess flow. For example, the airflow 111 is preferably an airflow that has a low flow velocity and forms a laminar flow with a predetermined Reynolds number or less. If the solvent 105 volatilizes from the liquid film 103 that is exposed to the airflow 111, as described above, the liquid film 104 that hardly flows planarly is obtained. The liquid film 104 follows the initial distribution of the droplets 102 arranged at a necessary density in each region, as shown in FIG. 2B. Hence, (the residual film of) the finally formed cured film 108 has an excellent in-plane distribution. In other words, the film (cured film) of the curable composition having an excellent film thickness distribution can be formed in the space between the mold 106 and the substrate 101.

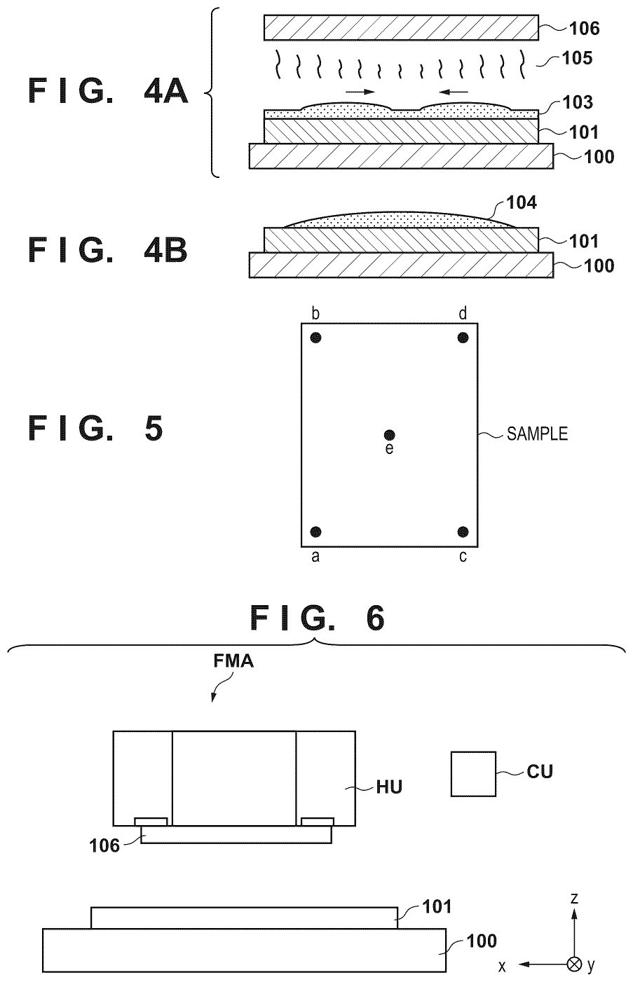

On the other hand, as a comparative example, a case where, in the waiting step, the liquid film 103 is not exposed to the airflow 111 when volatilizing the solvent 105 contained in the liquid film 103 will be described. FIG. 3A shows a state in which a structure 110 of a film forming apparatus exists in the space (opposing surface) above the liquid film 103 of the curable composition, and the airflow 111 including a flow of a gas parallel to the surface (upper surface) of the substrate 101 is not formed (the airflow 111 is absent). Here, unless the structure 110 exists at a position sufficiently apart from the liquid film 103, and the distance between the liquid film 103 and the structure 110 is a distance that does not affect the concentration of the solvent 105 volatilizing from the liquid film 103, the volatilization speed of the solvent 105 is affected by the structure 110. More specifically, the structure 110 that exists in the space above the liquid film 103 makes the volatilization speed of the solvent 105 volatilizing from the liquid film 103 uneven in plane. If the volatilization speed of the solvent 105 is uneven, the liquid film 103 may move to a region where the volatilization (speed) of the solvent 105 is slow, depending on the type of curable composition or solvent 105. As a result, as shown in FIG. 3B, the liquid film 104 obtained by volatilizing the solvent 105 does not follow the initial distribution of the droplets 102, and has a distribution different from the distribution of the liquid film 103 before the volatilization of the solvent 105. Hence, the film (cured film) of the curable composition having an excellent film thickness distribution cannot be formed in the space between the mold 106 and the substrate 101.

Also, as another comparative example, as shown in FIG. 4A, the waiting step in a case where a flat plate represented by the mold 106 exists in the space above the liquid film 103 of the curable composition, and the airflow 111 including a flow of a gas parallel to the surface of the substrate 101 is not formed will be described. In this case as well, the mold 106 existing in the space above the liquid film 103 makes the volatilization speed of the solvent 105 volatilizing from the liquid film 103 uneven in plane, unevenness occurs in the volatilization speed of the solvent 105, and the volatilization speed of the solvent 105 becomes higher on the outer periphery. Hence, the liquid film 103 moves to a region where the volatilization of the solvent 105 is slow, that is, from the outer periphery to the inner periphery, depending on the type of curable composition or solvent 105. As a result, as shown in FIG. 4B, the liquid film 104 obtained by volatilizing the solvent 105 has a small film thickness on the outer periphery, and the distribution of the liquid film 103 before the volatilization of the solvent 105 cannot be maintained. Hence, the film (cured film) of the curable composition having an excellent film thickness distribution cannot be formed in the space between the mold 106 and the substrate 101.

In the waiting step, the time for which the liquid film 103 containing the solvent 105 is exposed to the airflow 111 including a flow of a gas parallel to the surface of the substrate 101 is preferably decided based on the volatilization speed (evaporation speed) of the solvent 105. Since the time needed for volatilization changes depending on the solvent 105 contained in the liquid film 103 (curable composition), productivity can be improved by deciding (adjusting) the time for which the liquid film 103 is exposed the airflow 111 in accordance with the volatilization speed of the solvent 105. As a detailed example of numerical values, in the waiting step, the liquid film 103 is preferably exposed to the airflow 111 for 0.5 sec or more and 10 sec or less. In a combination of the curable composition and the solvent 105 whose volatilization is completed without taking 0.5 sec, the liquid film 103 cannot be formed because the droplets 102 do not sufficiently spread. On the other hand, in a combination of the curable composition and the solvent 105 whose volatilization is completed taking 10 sec or more, the productivity lowers.

In the waiting step, when forming the airflow 111 including a flow of a gas parallel to the surface (upper surface) of the substrate 101, the stage 100 holding the substrate 101 is driven in a direction parallel to the surface of the substrate 101. In other words, driving the stage 100 holding the substrate 101 in a direction parallel to the surface of the substrate 101 during volatilization of the solvent 105 contained in the liquid film 103 in the waiting step also constitutes one aspect of the present invention. When the stage 100 is driven in the direction parallel to the surface of the substrate 101, the liquid film 103 formed on the substrate 101 can be moved relatively to the ambient gas to form the airflow 111. When the stage 100 holding the substrate 101 is used, the liquid film 103 can be exposed to the airflow 111 without providing a dedicated mechanism for forming (generating) the airflow 111, and it is therefore advantageous in the viewpoint of simplifying the configuration. However, the present invention does not exclude providing a dedicated mechanism for forming the airflow 111.

Also, in the waiting step, when forming the airflow 111 by driving the stage 100 holding the substrate 101, the stage 100 is preferably driven in at least two different directions in plane of the substrate 101. Since the airflow 111 is formed in a plurality of directions, the volatilization of the solvent 105 is made more even by an averaging effect, and (the residual film of) the finally formed cured film 108 obtains a more excellent in-plane distribution. Note that the at least two directions for driving the stage 100 to form the airflow 111 preferably include two directions opposite to each other. For example, as shown in FIG. 2A, it is particularly preferable that the driving directions of the stage 100 include a first direction D1 and a second direction D2 opposite to the first direction D1. This can make the driving range of the stage 100 narrow and make the apparatus compact regardless of the necessary time for which the liquid film 103 is exposed to the airflow 111. Also, when driving of making the stage 100 reciprocally move in the first direction D1 and the second direction D2 is performed a plurality of times, it is possible obtain a higher averaging effect concerning volatilization of the solvent 105 while making the driving range of the stage 100 narrow.

### <Contact Step>

In the contact step, as schematically shown in FIG. 1E, the mold 106 is brought into contact with the practically continuous liquid film 104 of the curable composition from which the solvent 105 is removed. The contact step includes a step of a changing a state in which the curable composition on the substrate and the mold 106 are not in contact with each other to a state in which they are in contact with each other, and a step of maintaining the state in which they are in contact with each other. As a consequence, the liquid of the curable composition is filled in recesses of fine patterns on the surface of the mold 106, and the filled liquid forms a liquid film filled in the fine patterns of the mold 106.

When the curing step includes a photoirradiation step, a mold made of a light-transmitting material is used as the mold 106 by taking this into consideration. Favorable practical examples of the type of the material forming the mold 106 are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the mold 106, a resin that does not dissolve in components contained in a curable composition is selected. Quartz is suitable as the material forming the mold 106 because the thermal expansion coefficient is small and pattern distortion is small.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

In the curing step, as schematically shown in FIG. 1F, the curable composition is cured by being irradiated with irradiation light 107 as curing energy, thereby forming a cured film. In the curing step, for example, the curable composition is irradiated with the irradiation light 107 through the mold 106. More specifically, the curable composition filled in the fine pattern of the mold 106 is irradiated with the irradiation light 107 through the mold 106. Consequently, the curable composition filled in the fine pattern of the mold 106 is cured and forms a cured film 108 having the pattern.

The irradiation light 107 is selected in accordance with the sensitivity wavelength of the curable composition. More specifically, the irradiation light 107 is properly selected from ultraviolet light, X-ray, and an electron beam each having a wavelength of 150 nm or more and 400 nm or less. Note that the irradiation light 107 is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources. Light can be emitted to the entire region of the curable composition filled in the fine pattern of the mold, or to only a partial region thereof (by limiting the region). It is also possible to intermittently emit light to the entire region of the substrate a plurality of times, or to continuously emit light to the entire region of the substrate. Furthermore, a first region of the substrate can be irradiated with light in a first irradiation process, and a second region different from the first region of the substrate can be irradiated with light in the second irradiation process.

### <Mold Release Step>

In the mold release step, as schematically shown in FIG. 1G, the mold 106 is released from the cured film 108. When the mold 106 is released from the cured film 108 having the pattern, the film 108 having a pattern formed by inverting the fine pattern of the mold 106 is obtained in an independent state. In this state, a cured film remains in recesses of the cured film 108 having the pattern. This film is called a residual film.

A method of releasing the mold 106 from the cured film 108 having the pattern can be any method provided that the method does not physically break a part of the cured film 108 having the pattern during the release, and various conditions and the like are not particularly limited. For example, it is possible to fix the substrate 101 and move the mold 106 away from the substrate 101. It is also possible to fix the mold 106 and move the substrate 101 away from the mold 106. Furthermore, the mold 106 can be released from the cured film 108 having the pattern by moving both the mold 106 and the substrate 101 in exactly opposite directions.

A series of steps (a fabrication process) having the arranging step, the waiting step, the contact step, and the curing step, and the mold release step described above in this order makes it possible to obtain a cured film having a desired uneven pattern shape (a pattern shape conforming to the uneven shape of the mold 106) in a desired position.

### Example 1

Droplets of a liquid containing a curable composition and a solvent were arranged on a substrate using an inkjet method. Immediately after the liquid was arranged on the substrate, the stage holding the substrate was reciprocally driven in a distance (stroke) of 170 mm for 3 sec. Next, a mold made of quartz was brought into contact with the liquid arranged on the substrate, and after 5 sec, the liquid was irradiated with ultraviolet light of 10,000 W/m² from a UV lamp for 0.2 sec and thus cured, thereby forming a cured film. The mold was separated from the cured film formed on the substrate, thereby producing sample 1.

Using the same method as the production method of sample 1, only the waiting step was modified, and in the waiting step, the stage holding the substrate was made to wait under the mold for 30 sec, thereby producing sample 2.

Table 1 below shows a result of measuring, on each of sample 1 and sample 2 (sample), film thicknesses at five measurement points a, b, c, d, and e shown in FIG. 5 using a film thickness measuring device.

TABLE 1

| (nm) | Sample 1 | Sample 2 |
|---|---|---|
| a | 106.8 | 93.9 |
| b | 106.2 | 82.9 |
| c | 105.3 | 98.3 |
| d | 109.0 | 89.0 |
| e | 109.5 | 113.7 |
| 3σ | 5.4 | 35.0 |

Referring to Table 1, it can be found that, in sample 2, the film thicknesses at four points (measurement points a b, c, and d) on the outer periphery are smaller than the film thickness at one point at the center (measurement point e). On the other hand, it can be found that, in sample 1, the film thickness difference between the four points on the outer periphery and the one point at the center is small. Also, as is apparent from 3a, concerning variations of the in-plane thickness, sample 1 is more excellent than sample 2.

A film forming apparatus FMA as one aspect of the present invention will be described below with reference to FIG. 6. FIG. 6 is a schematic view illustrating the configuration of the film forming apparatus FMA. The film forming apparatus FMA is an apparatus that forms a film of a curable composition in the space between the mold 106 and the substrate 101. If the mold 106 includes a pattern, the film forming apparatus FMA is embodied as an imprint apparatus that forms a cured film having a pattern corresponding to the pattern of the mold 106. Also, if the mold 106 includes a flat surface, the film forming apparatus FMA is embodied as a planarization apparatus that forms a cured film having a surface conforming to the flat surface of the mold 106.

The film forming apparatus FMA includes a holding unit HU that holds the mold 106, the stage 100 that holds the substrate 101, and a control unit CU. The film forming apparatus FMA also includes, for example, a supply unit including a dispenser configured to arrange (supply) a curable composition on the substrate, a bridge surface plate configured to hold the holding unit H-1U, and a base surface plate configured to hold the stage 100.

The holding unit HU is a holding mechanism that holds the mold 106. The holding unit HU includes, for example, a chuck that vacuum-sucks or electrostatically attracts the mold 106, and a mold driving unit that drives the chuck. The mold driving unit drives (moves) the chuck sucking the mold 106, that is, the mold 106 in the X direction, the Y direction, the Z direction, and the OZ direction.

The stage 100 is a holding mechanism that holds the substrate 101. The stage 100, for example, vacuum-sucks or electrostatically attracts the substrate 101 via the chuck, and is driven by a substrate driving unit. The substrate driving unit drives the stage 100 holding the substrate 101, that is, the substrate 101 in the X direction, the Y direction, the Z direction, and the OZ direction.

The control unit CU is formed by an information processing apparatus (computer) including a CPU and a memory. The control unit CU generally controls the units of the film forming apparatus FMA in accordance with a program stored in a storage unit, thereby causing the film forming apparatus FMA to operate. The control unit CU controls processing of forming a film of a curable composition in the space between the mold 106 and the substrate 101. In this embodiment, the control unit CU executes the above-described film forming method in the film forming apparatus FMA. Particularly, in the waiting step, the control unit CU forms the airflow 111 including a flow of a gas parallel to the surface (upper surface) of the substrate 101 and the liquid film 103 formed on the substrate 101 is exposed to the airflow 111. At this time, the control unit CU, for example, drives the stage 100 in a direction parallel to the surface of the substrate 101, thereby forming the airflow 111.

The cured film (The pattern of a cured product) formed using the film forming apparatus FMA is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

Examples of the optical element are a quantum dot structure, a sub-wavelength antireflection structure, a light extraction structure such as an LED, a photonic crystal, a wire grid polarizing plate for UV region, a structural birefringent wavelength plate, a diffraction grating, and a metalens.

The cured film formed using the film forming apparatus FMA is directly used as the constituent member of at least some of the above-described articles or used temporarily as a resist mask. After etching or ion implantation is performed in the substrate processing step, the resist mask is removed.

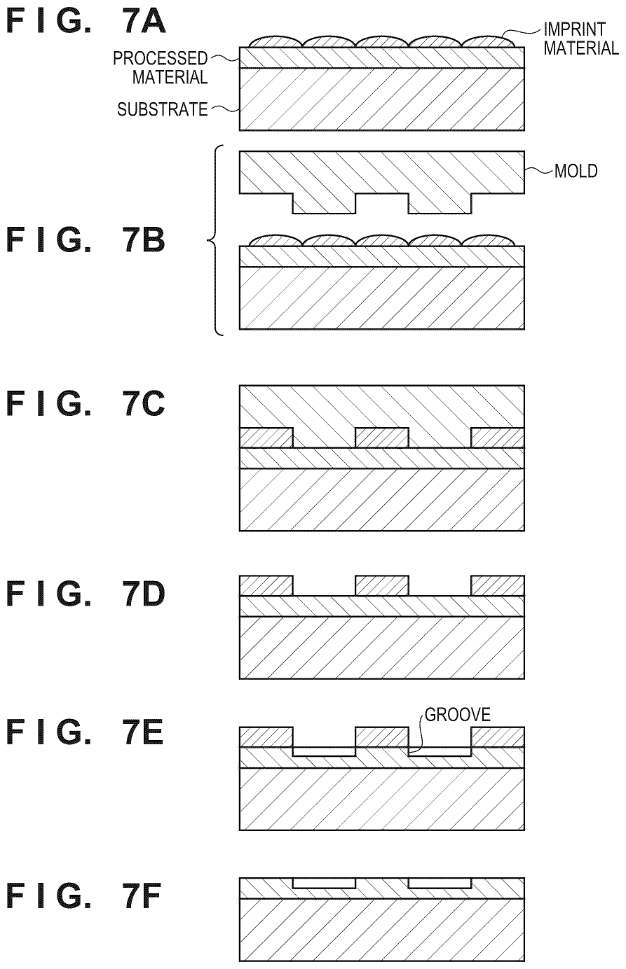

Next, description regarding a detailed method of manufacturing an article is given. As illustrated in FIG. 7A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 7B, a side of the mold for imprint with a projection and groove pattern is formed on and caused to face the imprint material on the substrate. As illustrated in FIG. 7C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 7D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 7E, when etching is performed using the pattern of the cured product as an etching resistant mask, a portion of the surface of the processed material where the cured product does not exist or remains thin is removed to form a groove. As shown in FIG. 7F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-191718 filed on Nov. 9, 2023, which is hereby incorporated by reference herein in its entirety.

What is claimed is:

1. A film forming method for forming a film of a curable composition in a space between a mold and a substrate, comprising:
discretely arranging a plurality of droplets of the curable composition on the substrate;
after the discretely arranging, waiting until the plurality of droplets combine with adjacent droplets to form a liquid film, and a solvent contained in the liquid film volatilizes;
after the waiting, bringing the liquid film and the mold into contact with each other;
after the bringing, curing the liquid film to form a cured film; and
after the curing, releasing the mold from the cured film,
wherein in the waiting, an airflow including a flow of a gas parallel to a surface of the substrate is formed and the liquid film is exposed to the airflow.

2. The method according to claim 1, wherein in the waiting, the liquid film is exposed to the airflow for not less than 0.5 sec and not more than 10 sec.

3. The method according to claim 1, wherein in the waiting, a stage holding the substrate is driven in a direction parallel to the surface of the substrate, thereby forming the airflow.

4. The method according to claim 3, wherein in the waiting, the stage is driven in at least two different directions in plane of the substrate, thereby forming the airflow.

5. The method according to claim 4, wherein the at least two directions include two directions opposite to each other.

6. The method according to claim 1, wherein in the waiting, driving of making a stage holding the substrate reciprocally move in a first direction parallel to the surface of the substrate and a second direction opposite to the first direction is performed a plurality of times, thereby forming the airflow.

7. The method according to claim 1, wherein the substrate includes a shot region on which the film should be formed, and
the waiting includes:
a first step until the liquid film covers a whole region of the shot region; and
a second step of waiting, after the first step, until the solvent contained in the liquid film covering the whole region volatilizes.

8. The method according to claim 1, wherein in the waiting, the liquid film is exposed to the airflow such that a volatilization speed of the solvent becomes even in plane.

9. The method according to claim 1, wherein the airflow includes a laminar flow.

10. The method according to claim 1, wherein the mold includes a pattern,
in the bringing, the pattern of the mold and the liquid film are brought into contact with each other, and
in the curing, a cured film having a pattern corresponding to the pattern of the mold is formed.

11. The method according to claim 1, wherein the mold includes a flat surface,
in the bringing, the flat surface of the mold and the liquid film are brought into contact with each other, and
in the curing, a cured film having a surface conforming to the flat surface of the mold is formed.

12. A film forming method for forming a film of a curable composition in a space between a mold and a substrate, comprising:
discretely arranging a plurality of droplets of the curable composition on the substrate;
after the discretely arranging, waiting until the plurality of droplets combine with adjacent droplets to form a liquid film, and a solvent contained in the liquid film volatilizes;
after the waiting, bringing the liquid film and the mold into contact with each other;
after the bringing, curing the liquid film to form a cured film; and
after the curing, releasing the mold from the cured film,
wherein in the waiting, a stage holding the substrate is driven in a direction parallel to a surface of the substrate until the solvent volatilizes.

13. An article manufacturing method comprising:
forming a film of a curable composition on a substrate using a film forming method defined in claim 1;
processing the substrate on which the film is formed in the forming; and
manufacturing an article from the processed substrate.

14. An article manufacturing method comprising:
forming a film of a curable composition on a substrate using a film forming method defined in claim 12;
processing the substrate on which the film is formed in the forming; and
manufacturing an article from the processed substrate.

15. A film forming apparatus for forming a film of a curable composition in a space between a mold and a substrate, comprising:
a control unit configured to control processing of forming the film,
wherein the processing includes:
discretely arranging a plurality of droplets of the curable composition on the substrate;
after the discretely arranging, waiting until the plurality of droplets combine with adjacent droplets to form a liquid film, and a solvent contained in the liquid film volatilizes;
after the waiting, bringing the liquid film and the mold into contact with each other;
after the bringing, curing the liquid film to form a cured film; and
after the curing, releasing the mold from the cured film, and
in the waiting, the control unit forms an airflow including a flow of a gas parallel to a surface of the substrate, and the liquid film is exposed to the airflow.

16. The apparatus according to claim 15, further comprising a stage configured to hold the substrate,
wherein in the waiting, the control unit forms the airflow by driving the stage in a direction parallel to the surface of the substrate.
